(19) United States
(12) Patent Application Publication
(10) Pub. No.: US 2013/0157043 A1
(43) Pub. Date: Jun. 20, 2013

(54) COATED ARTICLE AND METHOD FOR MANUFACTURING SAME

(71) Applicant: DA-HUA CAO, Shenzhen City (CN)

(72) Inventor: DA-HUA CAO, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/443,491

(22) Filed: Apr. 10, 2012

(30) Foreign Application Priority Data
Dec. 17, 2011 (CN) 201110423663.0

(51) Int. Cl. B32B 15/04; C23C 14/35; C23C 14/34; B32B 9/00; B32B 5/00

(52) U.S. Cl. 428/336; 428/698; 428/457; 428/332; 204/192.1; 204/192.15

(57) ABSTRACT

A coated article includes a substrate, a color layer deposited on the substrate. The color layer includes a plurality of first CrC layers and first TiC layers. Each first CrC layer is alternately arranged with each first TiC layer. The color layer have an L* value between about 29 to about 35, an a* value between about 0 to about 2, and a b* value between about 0 to about 2 in the CIE L*a*b* color space. A method for manufacturing the coated article is also provided.

### BACKGROUND

1. Technical Field

The exemplary disclosure generally relates to a coated article and a method for manufacturing the coated article.

2. Description of Related Art

Vacuum deposition is used to form thin films or coatings on housings of portable electronic devices to improve abrasion resistance of the housings. However, typical vacuum deposition film cannot present an absolute black color which has a “L” value less than 35 (i.e., in the CIE L*a*b* (international commission of illumination) color space).

Therefore, there is room for improvement within the art.

### BRIEF DESCRIPTION OF THE DRAWINGS

Many aspects of the embodiment can be better understood with reference to the following drawings. The components in the drawings are not necessarily drawn to scale, the emphasis instead being placed upon clearly illustrating the principles of the exemplary disclosure. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of a first exemplary embodiment of a coated article.

FIG. 2 is a cross-sectional view of a second exemplary embodiment of a coated article.

FIG. 3 is a schematic view of a vacuum sputtering device for manufacturing the coated article shown in FIGS. 1 and 2.

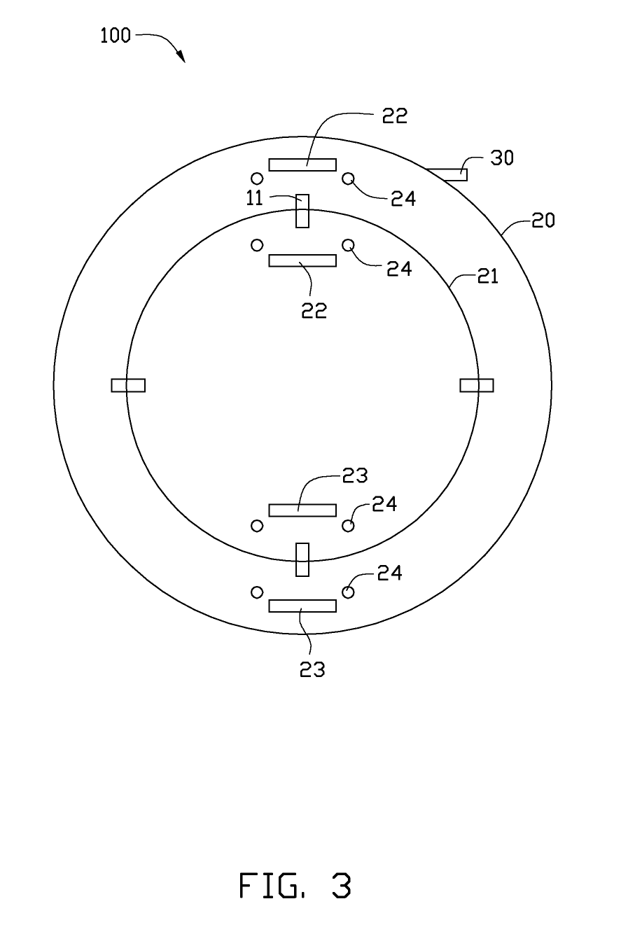

### DETAILED DESCRIPTION

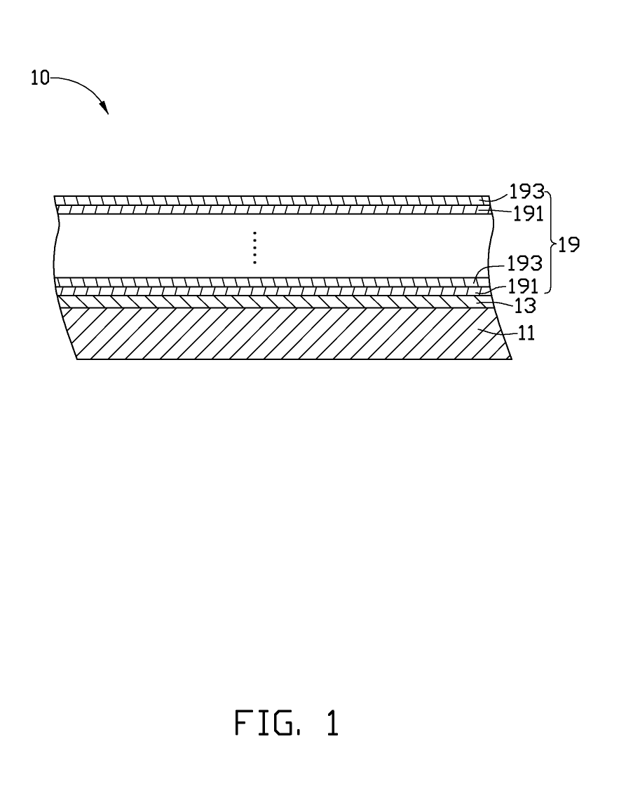

FIG. 1 shows a first exemplary embodiment of a coated article. The coated article 10 includes a substrate 11, a Cr primer layer 13 formed on the substrate 11, and a color layer 19 formed on the Cr primer layer 13. The coated article 10 can be a housing of a mobile phone, a personal digital apparatus (PDA), a notebook computer, a portable music player, a GPS navigator, or a digital camera.

The substrate 11 may be made of metal, such as stainless steel, aluminum, aluminum alloy, magnesium or magnesium alloy. Alternately, the substrate 11 may be made of nonmetal material, such as glass, ceramic, or plastic.

The Cr primer layer 13 improves a bonding force between the substrate 11 and the color layer 19. The Cr primer layer 13 may be a chromium (Cr) layer. The Cr primer layer 13 has a thickness of about 0.05 μm to about 0.1 μm.

The color layer 19 includes a plurality of first CrC layers 191 and first TiC layers 193. Each first CrC layer 191 is alternately arranged with each first TiC layer 193. A first CrC layer 191 or a first TiC layer 193 is directly formed on the Cr primer layer 13. As used in this disclosure, “directly” means a surface of one layer is in contact with a surface of the other layer. The outermost layer of the color layer 19 is one of the first CrC layers 191 or one of the first TiC layers 193. The color layer 19 has a thickness of about 0.05 μm to about 0.2 μm.

The color layer 19 has an L* value between about 29 to about 35, an a* value between about 0 to about 2, and a b* value between about 0 to about 2 in the CIE L*a*b* color space. The color layer 19 presents an absolute black color having the L* value less than 35.

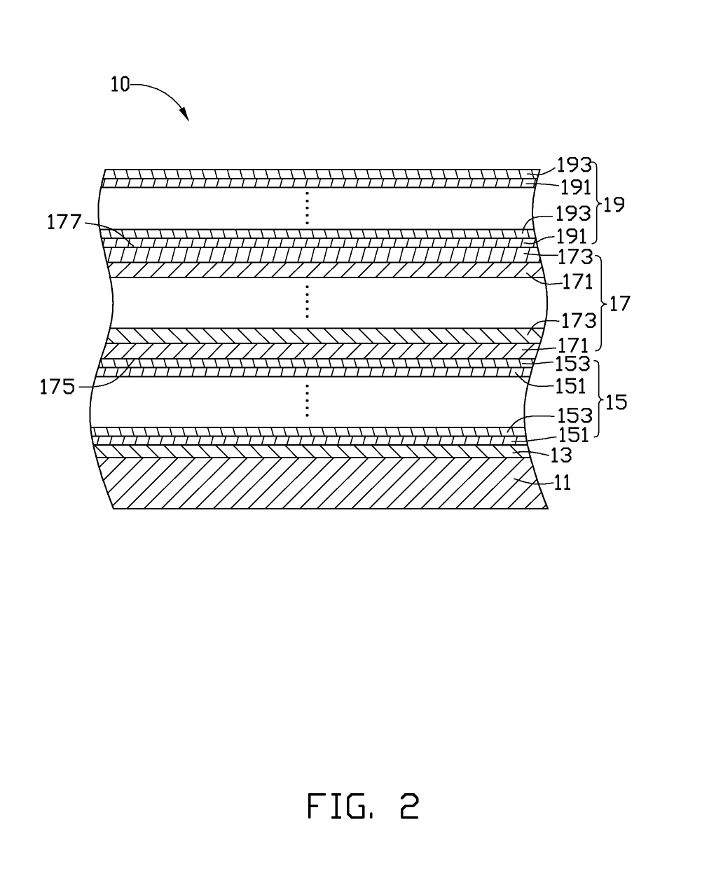

FIG. 2 shows a second exemplary embodiment of a coated article. In the second exemplary embodiment, the coated article 10 further includes a transition layer 15 formed on the Cr primer layer 13, and a gradient layer 17 formed on the transition layer 15. The transition layer 15 and the gradient layer 17 improve the bonding force between the Cr primer layer 13 and the color layer 19, and to reduce the internal stress of the layers 13-19.

The transition layer 15 includes a plurality of second CrC layers 151 and TiC layers 153. Each CrC layer 151 is alternately arranged with each TiC layer 153. A CrC layer 151 is directly formed on the Cr primer layer 13. A CrC layer 151 or a TiC layer 153 is directly bonded to the gradient layer 17. The transition layer 15 has a thickness of about 0.08 μm to about 0.2 μm.

The gradient layer 17 includes a plurality of third CrC layers 171 and third TiC layers 173. Each third TiC layer 171 is alternately arranged with each third TiC layer 173. The gradient layer 17 includes a first surface 175 and an opposite second surface 177. Each third CrC layer 171 has a different atomic carbon content as compared with the other third CrC layer 171 of the gradient layer 17, and each third TiC layer 173 has different atomic carbon content as compared with the other TiC layers 173 of the gradient layer 17. The atomic carbon content in the gradient layer 17 gradually increases from a lower value in the area of the first surface 175 to a value higher than the lower value in the area of the second surface 177. A third CrC layer 171 or a third TiC layer 173 is directly formed on the transition layer 15. A third CrC layer 171 or a third TiC layer 173 is directly bonded to the color layer 19. The gradient layer 17 has a thickness of about 0.5 μm to about 1.2 μm.

A method for manufacturing the coated article 10 may include at least the following steps:

The substrate 11 is provided. The substrate 11 may be made of metal, such as stainless steel, aluminum, aluminum alloy, magnesium or magnesium alloy. Alternately, the substrate 11 may be made of non-metal material, such as glass, ceramic, or plastic.

The substrate 11 is cleaned using a cleaning solution. The cleaning solution can be ethanol, acetone and/or other organic solvents. A conventional ultrasonic cleaning device can be used to clean the substrate 11.

Referring to FIG. 2, a vacuum sputtering device 100 is provided. The vacuum sputtering device 100 includes a chamber 20, a vacuum pump 30 connected to the chamber 20, and a conventional film thickness monitor (not shown) installed in the chamber 20. The vacuum pump 30 is used to evacuate the chamber 20. The film thickness monitor measures the thickness of layer, not only after it has been made, but while it is being deposited. The vacuum sputtering device 100 further includes a rotating bracket 21, two Cr targets 22 and two Ti targets 23 mounted therein, and a plurality of gas inlets 24. The rotating bracket 21 rotates the substrate 11 in the chamber 20 relative to the Cr targets 22 and the Ti targets 23. The two Cr targets 22 face each other, and are located on opposite two sides of the rotating bracket 21. The two Ti targets 23 face each other, and are located on the opposite two sides of the rotating bracket 21. Cr targets Ti targets

The substrate 11 is cleaned by argon gas (Ar) plasma. The substrate 11 is mounted on the rotating bracket 21 in the chamber 20. The chamber 20 is evacuated to about 4×10⁻³Pa to about 7×10⁻³Pa. During depositing, the rotating bracket 21 rotates in the chamber 20 with a rate in a range from about 1 revolution per minute (rpm) to about 4 rpm. Argon gas is fed into the chamber 20 at a flux rate about 250 Standard Cubic Centimeters per Minute (sccm) to about 350 sccm by the gas inlets 24. A bias voltage of about −800 volts (V) to about −1200 V may be applied to the substrate 11. Plasma cleaning the substrate 11 may take about 10 min to about 30 min.

The Cr primer layer 13 is deposited on the substrate 11. The Cr primer layer 13 is a Cr layer. The temperature of the inside of the chamber 20 is set to about 100° C. (Celsius degree) to about 150° C. Argon gas may be used as a working gas and is fed into the chamber 20 at a flow rate from about 150 sccm to about 200 sccm. The Cr targets 22 in the chamber 20 are applied a power between about 10 kW to about 20 kW. A bias voltage of about −50 V to about −200 V is then applied to the substrate 11 to deposit the Cr primer layer 13. Depositing the Cr primer layer 13 may last for about 5 minutes to about 10 minutes. The Cr primer layer 13 has a thickness of about 0.05 μm to about 0.1 μm.

Next, a color layer 19 is deposited on the Cr primer layer 13. The temperature of the inside of the chamber 20 is set to about 100° C. (degrees Celsius) to about 150° C. Argon gas may be used as a working gas and is fed into the chamber 20 at a flow rate from about 150 sccm to about 200 sccm. Ethyne (C₂H₂) may be used as a reaction gas, and the ethyne may have a flow rate of about 160 sccm to about 240 sccm. The Cr targets 22 in the chamber 20 are applied a power between about 15 kW to about 20 kW. The Ti targets 23 in the chamber 20 are applied a power between about 10 kW to about 15 kW. A bias voltage of about −100 V to about −200 V is applied to the substrate 11 to deposit the color layer 19. Depositing the color layer 19 may last for about 5 minutes to 15 minutes. During depositing the color layer 19, a first CrC layer 191 will be deposited on the Cr primer layer 13 when the substrate 11 passes the powered Cr targets 22, and a first TiC layer 193 will be deposited on the Cr primer layer 13 when the substrate 11 passes the powered Ti targets 23. Thus a plurality of first CrC layers 191 and first TiC layers 193 are alternately formed on the Cr primer layer 13.

The color layer 19 has an L* value between about 29 to about 35, an a* value between about 0 to about 2, and a b* value between about 0 to about 2 in the CIE L*a*b*.

In the second exemplary embodiment, the method for manufacturing the coated article 10 further includes depositing a transition layer 15 on the Cr primer layer 13, and depositing a gradient layer 17 on the transition layer 15.

Depositing the transition layer 15 on the Cr primer layer 13 may be carried out as follows. The temperature of the inside of the chamber 20 is set to about 100° C. to about 150° C. Argon gas may be used as a working gas and is fed into the chamber 20 at a flow rate from about 150 sccm to about 200 sccm. The Cr targets 22 in the chamber 20 are applied a power between about 15 kW to about 20 kW. The Ti targets 23 in the chamber 20 are applied a power between about 10 kW to about 15 kW. A bias voltage of about −100 V to about −200 V is applied to the substrate 11. Depositing the transition layer 15 may last for about 5 minutes to about 10 minutes. During depositing the transition layer 15, a CrC layer 151 will be deposited on the Cr primer layer 13 when the substrate 11 passes the powered Cr targets 22, and a TiC layer 153 will be deposited on the Cr primer layer 13 when the substrate 11 passes the powered Ti targets 23. Thus a plurality of CrC layers 151 and TiC layers 153 are alternately formed on the Cr primer layer 13.

The gradient layer 17 is deposited on the transition layer 15. The temperature of the inside of the chamber 20 is set to about 100° C. to about 150° C. Argon gas may be used as a working gas and is fed into the chamber 20 at a flow rate from about 150 sccm to about 200 sccm. Ethyne (C₂H₂) gas may be used as reaction gas, and the ethyne may have a flow rate of about 50 sccm to about 110 sccm. The Cr targets 22 in the chamber 20 are applied a power about 15 kW to about 20 kW. The Ti targets 23 in the chamber 20 are applied a power about 10 kW to about 15 kW. A bias voltage of about −100 V to about −200 V is applied to the substrate 11. Depositing the gradient layer 17 lasts for about 80 minutes to about 120 minutes. During the depositing process, the flow rate of the ethyne is increased from about 0.5 sccm to about 2 sccm every 4 minutes. Thus, the atomic carbon content in the gradient layer 17 gradually increases from a lower value in the area of the first surface 175 to a value higher than the lower value in the area of the second surface 177. In other words, the atomic carbon content in the gradient layer 17 gradually increases from near the transition layer 15 to away from the transition layer 15. During depositing the gradient layer 17, a third CrC layer 171 will be deposited on the transition layer 15 when the substrate 11 passes the powered Cr targets 22, and a third TiC layer 173 will be deposited on the transition layer 15 when the substrate 11 passes the powered Ti targets 23. Thus a plurality of third CrC layers 171 and third TiC layers 173 are alternately formed on the transition layer 15.

The hardness of the coated article 10 in the embodiment gradually increases from the Cr primer layer 13 to the gradient layer 17. Thus large differences in internal stresses will not exist between the Cr primer layer 13, the transition layer 15, and the gradient layer 17, which improves the bonding force between the layers 13-17. Additionally, the atomic carbon content of the gradient layer 17 gradually increases from near the transition layer 15 to away from the transition layer 15, allows the coefficient of thermal expansion of the gradient layer 17 near the transition layer 15 to be low and close to that of the transition layer 15, and allows the coefficient of thermal expansion of the gradient layer 17 near the color layer 19 to be high and close to that of the color layer 19, thus further reducing the internal stress difference between the transition layer 15, the gradient layer 17, and the color layer 19. Since the layers 13-19 have low internal stress differences, the bonding force between the layers 13-19 and to the substrate 11 are greatly enhanced, and the abrasion resistance of the coating 10 is also enhanced.

### EXAMPLES

Experimental examples of the present disclosure are described as follows.

### Example 1

Depositing the Cr primer layer 13: the flow rate of argon gas was about 150 sccm; a power of 14 kW was applied to the Cr targets 22; the speed of the rotating bracket 21 was about 4 rpm; the temperature in the chamber 20 was set to about 130° C.; a bias voltage of —100 V was applied to the substrate 11; sputtering of the Cr primer layer 13 take about 8 min.

Depositing the color layer 19: the flow rate of ethyne was about 180 sccm; a power of 15 kW was applied to the Cr targets 22, and a power of 12 kW was applied to the Ti targets 23; the temperature in the chamber 20 was set to about 135° C.; a bias voltage of −100 V was applied to the substrate 11; sputtering of the color layer 19 take about 10 min.

### Example 2

Depositing the Cr primer layer 13: the flow rate of argon gas is about 150 sccm; a power of 14 kW was applied to the Cr targets 22; the speed of the rotating the bracket 21 was about 4 rpm; the temperature in the chamber 20 was set to about 130° C.; a bias voltage of −100 V was applied to the substrate 11; sputtering of the Cr primer layer 13 take about 8 min.

Depositing the transition layer 15: the flow rate of argon gas was about 150 sccm; a power of about 15 kW is applied to the Cr targets 22 and a power of about 12 kW is applied to the Ti targets 23; the speed of the rotating the bracket 21 was about 4 rpm; the temperature in the chamber 20 was set to about 135 V; a bias voltage of −100 V was applied to the substrate 11; sputtering of the transition layer 15 take about 8 min.

Depositing the gradient layer 17: the flow rate of argon gas was 150 sccm and the flow rate of ethyne was about 50 sccm; a power of about 15 kW was applied to the Cr targets 22 and a power of about 12 kW was applied to the Ti targets 23; the speed of the rotating bracket 21 was about 4 rpm; the temperature in the chamber 20 was set to about 135° C.; a bias voltage of −100 V was applied to the substrate 11; sputtering of the transition layer 15 take about 120 min. During depositing gradient layer 17, the flow rate of the ethyne was increased about 1 sccm every 4 minutes.

Depositing the color layer 19: the flow rate of ethyne is 180 about sccm; a power of about 15 kW was applied to the Cr targets 22 and 12 kW of power was applied to the Ti targets 23; the temperature in the chamber 20 was set to about 135 V; a bias voltage of −100 V was applied to the substrate 11; sputtering of the color layer 19 take about 10 min.

### Example 3

Depositing the Cr primer layer 13: the flow rate of argon gas was about 180 sccm; a power of about 16 kW was applied to the Cr targets 22; the speed of the rotating bracket 21 was about 5 rpm; the temperature in the chamber 20 was set to about 120° C.; a bias voltage of −120 V was applied to the substrate 11; sputtering of the Cr primer layer 13 take about 5 min.

Depositing the transition layer 15: the flow rate of argon gas was about 180 sccm; a power of about 17 kW was applied to the Cr targets 22 and a power of about 13 kW was applied to the Ti targets 23; the speed of the rotating the bracket 21 was 5 rpm; the temperature in the chamber 20 was set to about 125° C.; a bias voltage of −150 V was applied to the substrate 11; sputtering of the transition layer 15 take about 5 min.

Depositing the gradient layer 17: the flow rate of argon gas was 150 sccm and the flow rate of ethyne was about 70 sccm; a power of about 17 kW was applied to the Cr targets 22 and a power of about 13 kW was applied to the Ti targets 23; the speed of the rotating the bracket 21 was 5 rpm; the temperature in the chamber 20 was set to about 125° C.; a bias voltage of −150 V was applied to the substrate 11; sputtering of the transition layer 15 take about 120 min. During depositing gradient layer 17, the flow rate of the ethyne was increased about 1 sccm every 4 minutes.

Depositing the color layer 19: the flow rate of ethyne was about 200 sccm; a power of about 17 kW was applied to the Cr targets 22 and a power of 13 kW was applied to the Ti targets 23; the temperature in the chamber 20 was set to about 125° C.; a bias voltage of −150 V was applied to the substrate 11; sputtering of the color layer 19 take about 10 min.

CIE Lab Test

Example 1: The color layer 19 has an L* value of 30, an a* value of 1.5, and a b* value of 1.0 in the CIE L*a*b* (CIE LAB) color space.

Example 2: The color layer 19 has an L* value of 30, an a* value of 1.5, and a b* value of 1.0 in the CIE L*a*b* (CIE LAB) color space.

Example 3: The color layer 19 has an L* value of 32, an a* value of 1.0, and a b* value of 1.0 in the CIE L*a*b* (CIE LAB) color space.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coated article, comprising:
a substrate; and
a color layer deposited on the substrate, the color layer comprising a plurality of first CrC layers and first TiC layers, each first CrC layer being alternately arranged with each first TiC layer, the color layer having an L* value between about 29 to about 35, an a* value between about 0 to about 2, and a b* value between about 0 to about 2 in the CIE L*a*b* color space.

2. The coated article as claimed in claim 1, wherein the color layer has a thickness of about 0.05 μm to about 0.2 μm.

3. The coated article as claimed in claim 1, wherein the substrate is made of metal or nonmetal material.

4. The coated article as claimed in claim 1, wherein the coated article further comprises a transition layer formed between the substrate and the color layer.

5. The coated article as claimed in claim 4, wherein the transition layer comprises a plurality of CrC layers and TiC layers, and each CrC layer is alternately arranged with each TiC layer.

6. The coated article as claimed in claim 5, wherein the transition layer has a thickness of about 0.08 μm to about 0.2 μm.

7. The coated article as claimed in claim 4, wherein the coated article further comprises a gradient layer formed between the transition layer and the color layer.

8. The coated article as claimed in claim 7, wherein the gradient layer comprises a plurality of third TiC layers and third TiC layers, and each third TiC layer is alternately arranged with each third TiC layer.

9. The coated article as claimed in claim 8, wherein the gradient layer comprises a first surface and an opposite second surface, each third CrC layer has different carbon content atoms as compared with the other third CrC layers of the gradient layer, each third TiC layer also has different carbon content atoms as compared with the other third TiC layers of the gradient layer; the atomic carbon content in the gradient layer gradually increases from a lower value in the area near the first surface to a value higher than the lower value in the area near the second surface.

10. The coated article as claimed in claim 7, wherein the gradient layer has a thickness of about 0.5 μm to about 1.2 μm.

11. The coated article as claimed in claim 4, wherein the coated article further comprises a Cr primer layer formed between the substrate and the transition layer Cr primer layer.

12. The coated article as claimed in claim 11, wherein the Cr primer layer has a thickness of about 0.05 μm to about 0.1 μm.

13. A method for manufacturing a coated article, comprising steps of:
providing a substrate; and
depositing a color layer on the substrate by vacuum sputtering, the color layer comprising a plurality of first CrC layers and first TiC layers, each first CrC layers being alternately arranged with each first TiC layers; the color layer having an L* value between about 29 to about 35, an a* value between about 0 to about 2, and a b* value between about 0 to about 2 in the CIE L*a*b* color space.

14. The method of claim 13, wherein during deposition of the color layer on the substrate, the substrate is mounted on a chamber of a vacuum sputtering device, the vacuum sputtering device comprises Cr targets and Ti targets Cr targets Ti targets; the temperature of the inside of the chamber is set to about 100° C. to about 150° C.; ethyne used as a reaction gas and ethyne have a flow rate from about 160 sccm and 240 sccm; sputtering the Cr targets and the Ti targets at the same time, the Cr targets are applied a power between about 15 kW to about 20 kW, the Ti targets are applied a power between about 10 kW to about 15 kW; a bias voltage of −100 volts to about −200 volts is applied to the substrate for about 5 minutes to about 15 minutes.

15. The method of claim 13, wherein the method further comprises a step of depositing a transition layer on the substrate by magnetron sputtering before depositing the color layer on the substrate, the transition layer comprises a plurality of CrC layers and TiC layers, each CrC layers is alternately arranged with each TiC layers; during depositing the transition layer, the temperature of the inside of the chamber is set to about 100° C. to about 150° C., argon gas used as a working gas and have a flow rate from about 150 sccm to about 200 sccm, sputtering the Cr targets and the Ti targets at the same time, the Cr targets is applied a power about 15 kW to about 20 kW and the Ti targets is applied a power about 10 kW to about 15 kW; and a bias voltage is applied to the substrate about −100 volts to about −200 volts for about 5 min to about 10 min, to deposit the transition layer on the substrate.

16. The method of claim 15, wherein the method further comprises a step of depositing a gradient layer on the transition layer by magnetron sputtering before depositing the color layer on the substrate, the gradient layer comprises a plurality of alternating third TiC layers and third TiC layers, and each third TiC layers is alternately arranged with each third TiC layers; wherein during depositing the transition layer, the temperature in the vacuum chamber is adjusted in a range from 100° C. to 150° C., argon gas used as a working gas and have a flow rate from about 150 sccm to about 200 sccm, ethyne used as reaction gases and have a flow rate of about 50 sccm to about 110 sccm; sputtering the Cr targets and the Ti targets at the same time, the Cr targets is applied a power from about 15 kW to about 20 kW and the Ti targets is applied a power from about 10 kW to about 15 kW; and a bias voltage of about −100 volts to about −200 volts is applied to the substrate for about 80 min to about 120 min, to deposit the gradient layer on the substrate.

17. The method of claim 15, wherein the method further comprises a step of depositing a Cr primer layer on the substrate before depositing the transition layer on the substrate Cr primer layer.
